(19) United States
(12) Patent Application Publication
(10) Pub. No.: US 2019/0296169 A1
(43) Pub. Date: Sep. 26, 2019

(54) THIN-FILM PHOTOVOLTAIC DEVICE AND ASSOCIATED METHOD OF FABRICATION

(71) Applicants: ELECTRICITE DE FRANCE, Paris (FR); PARIS SCIENCES ET LETTRES - QUARTIER LATIN, Paris (FR); CENTRE NATIONAL DE LA RECHERCHE SCIENTIFIQUE- CNRS, Paris (FR)

(72) Inventors: Myriam Paire, Paris (FR); Aurelien Duchatelet, Neauphle le Vieux (FR); Pierre-Philippe Grand, Saint-Maximin la Sainte Baume (FR); Sebastien Jutteau, Marly le Roi (FR)

(21) Appl. No.: 16/302,389

(22) PCT Filed: May 12, 2017
(86) PCT No.: PCT/EP2017/061514

§ 371 Date: Nov. 16, 2018

(30) Foreign Application Priority Data
May 20, 2016 (FR) 16 54559

(51) Int. Cl. H01L 31/0465; H01L 31/054; H01L 31/0463

(52) U.S. Cl. CPC H01L 31/0465; H01L 31/0463; H01L 31/0547

(57) ABSTRACT

A thin-film photovoltaic device is proposed having an optimized layout for one of the electrical contacts. The device comprises a substrate. A first thin film forming a first electrical contact of the photovoltaic device is arranged on the substrate. An absorber is arranged on the first electrical contact. A second thin film forming a second electrical contact of the photovoltaic device is arranged on the substrate. A transparent conductive layer is arranged on the absorber. In addition, the second electrical contact is spaced apart from the first electrical contact, and the transparent conductive layer is in contact with the absorber and the second electrical contact.

### TECHNICAL FIELD

The invention relates to the field of thin-film photovoltaic devices. The invention applies in particular to the fabrication of electrical contacts in thin-film photovoltaic devices, for example such as photovoltaic devices equipped with a light concentrator.

### BACKGROUND

Solar cells are photovoltaic devices comprising a material with photovoltaic properties called an absorber, which converts the energy of the incident light reaching the cell into electric current. The current thus generated is collected by electrical contacts distributed on each side of the absorber.

To increase the performance of photovoltaic devices, electrical contacts of good quality need to be fabricated that are placed near the absorber while allowing the incident light to reach the absorber.

One problem that arises in the fabrication of electrical contacts in a photovoltaic device is the arrangement of these contacts relative to the absorber. It is desirable to position the electrical contacts as close as possible to the absorber, but without covering the absorber. The farther the electrical contacts are from the absorber, the more the resistive losses during the flow of current from the absorber to the electrical contacts increases. However, the positioning of electrical contacts as close as possible to the absorber encounters several difficulties.

In the context of crystalline solar cells, the absorber comes from a wafer divided into cells, the cells then being assembled on a photovoltaic panel. Crystalline solar cells are based on fabrication technologies which increase in cost with the number of solar cells used for a panel of fixed size.

This problem of positioning the cell relative to the electrical contacts is a particular concern in “light-concentrating” photovoltaic devices. A “light-concentrating” photovoltaic device further comprises an optical system concentrating the light on a reduced area of the substrate, on the absorber, the absorber covering only a fraction of the surface of the photovoltaic panel. In these devices, a smaller amount of absorber is necessary because the incident light is focused on a small area of the solar panel. However, the positioning of an absorber having reduced dimensions in a light-concentrating photovoltaic device requires even greater precision.

In light-concentrating systems, the light intensity received by the absorber is higher than in photovoltaic devices without any light concentrators. As a result, the resistive losses between the absorber and the electrical contacts are even greater in a light-concentrating photovoltaic device, and therefore prompt the search for means for positioning electrical contacts as close as possible to the absorber.

One solution for more precisely controlling the placement of electrical contacts relative to the absorber is to opt for the use of thin-film solar cells. Thin-film photovoltaic devices are also highly attractive because of their lower fabrication costs than crystalline solar cells, and the use of fabrication techniques suitable for industrial applications such as electrodeposition, co-evaporation, sputtering, or ink printing.

“Thin-film photovoltaic device” is understood to mean a device comprising materials in the form of a layer having a thickness typically varying from a few atomic layers to about ten micrometers. The concept of a thin-film device is known to those skilled in the art, particularly in the photovoltaic field.

Electrodeposition and printing are selective deposition techniques that allow using less material for fabricating thin films.

Selective deposition is understood to mean a deposition where the location of the deposited material depends on the chemical and/or electrical nature of the substrate on which the deposition occurs. With selective deposition it is typically sufficient to provide a substrate whose properties vary spatially. For example, if a substrate has hydrophilic and hydrophobic areas, aqueous liquids can be thermodynamically drawn to the hydrophilic areas. If the substrate has electrically conductive and insulating areas, electrodeposition could occur on the conductive area only. Thus, selective deposition is in contrast to depositions through a mask or to a deposition plus a structuring step. For example, printing in which the motorized printing nozzle is moved in order to deposit drops on a substrate is not necessarily selective. Conversely, printing in which a substrate is immersed in an ink bath and the ink is only drawn to certain points due to a hydrophilic/hydrophobic contrast, is considered to be selective.

Electrodeposition may be used to create the various constituent layers of a light-concentrating photovoltaic device, as described in WO 2011/151338. However, despite the many advantages offered by electrodeposition methods in terms of control and precision in positioning the electrical contacts, the methods for fabricating thin-film photovoltaic devices have other constraints which make it difficult to obtain quality electrical contacts as close as possible to the absorber.

The fabrication of a thin-film solar cell generally comprises annealing steps involving temperatures above 500° C. To prevent damage to the electrical contacts in these conditions, the electrical contact associated with the upper surface of the absorber is generally fabricated at the end of the cell fabrication process. In this configuration, the electrical contact on the front face of the thin-film photovoltaic device rests on an upper portion of the absorber, and may therefore obscure a portion of it. This arrangement of the electrical contact on the front surface of the photovoltaic device is therefore unsatisfactory.

Patent WO 2011/151338 proposes a significantly different arrangement in which the electrical contact is deposited on a structured insulating layer in a manner that leaves openings above the absorber for depositing an electrically conductive and transparent window layer. The electrical contact is arranged as close as possible to the absorber without covering it, the current being able to flow from the absorber to the electrical contact through the window layer. However, such an arrangement involves a complex and expensive fabrication step for creating the structured insulating layer and the subsequent deposition of the electrical contact on the upper surface of this insulating layer. In addition, the opaque electrical contact then covers a large portion of the solar panel, rendering it opaque so that only a small portion of the panel is actually used to convert light to electricity.

A photovoltaic device is therefore desired where the electrical contacts do not cover the absorber and are arranged as close as possible to the absorber, as well as a method for fabricating this device that is simple and inexpensive.

### DISCLOSURE OF THE INVENTION

To address the problems outlined above, the present invention proposes a thin-film photovoltaic device comprising:
a substrate.
at least a first electrically conductive thin layer forming a first electrical contact of the photovoltaic device on the substrate,
an absorber arranged on the first electrical contact.
at least a second electrically conductive thin layer forming a second electrical contact of the photovoltaic device on the substrate,
a transparent conductive layer arranged on the absorber,
   the second electrical contact being spaced apart from the first electrical contact, and the transparent conductive layer being in contact with the absorber and the second electrical contact.

The invention thus provides a thin-film photovoltaic device in which the two electrical contacts are arranged on a substrate, on the same side of the substrate as the absorber layer. This arrangement differs from the electrical contacts of the prior art which are based on at least one electrical contact being arranged on an upper surface of the photovoltaic device and not on the substrate, in order to maintain a gap between the two electrical contacts and prevent short-circuiting. The invention, by arranging the two contacts on the same surface of the substrate, on the same side of the substrate as the absorber, while maintaining a gap between the two electrical contacts, simplifies the arrangement of the device and avoids obscuring the absorber layer.

This structuring of the two electrical contacts of a photovoltaic device has the further advantage of allowing simplified fabrication of the two contacts, during or before the deposition of the absorber, for example using etching techniques. The space between the two electrical contacts can therefore be controlled with greater precision than in techniques involving deposition onto an upper surface of the absorber. The transparent electrically conductive layer allows current to flow from the absorber to the second electrical contact, while covering the space between the first electrical contact and the second electrical contact.

According to one embodiment, the second electrical contact and the first electrical contact may be structured in an interleaved manner.

“Interleaved” is understood to mean a structure where the first contact comprises protrusions arranged opposite to complementarily shaped portions created in the second contact. A typical example of an interleaved structure for both contacts resembles two combs fitted into one another. Other structures having first and second contacts of complementary shapes, maintaining a substantially constant gap between the first and second contacts along their mutually facing portions, are conceivable.

The use of an interleaved structure has the advantage of distributing the second electrical contact over a large surface area around the absorber, while limiting the extent of the second electrical contact on the substrate. Indeed, the second electrical contact may follow the shape of the absorber over at least some of the peripheral portion of the absorber, thereby allowing a higher current density to pass from the absorber to the second electrical contact by crossing the space between the absorber and the second electrical contact. The interleaved structure thus contributes to reducing the resistive losses.

According to one embodiment, the second electrical contact may comprise each of the layers of the first electrical contact.

A photovoltaic device in which the second electrical contact comprises each of the layers of the first electrical contact may be achieved by a single etching process. The second electrical contact may be structured by etching in a layer of the constituent material of the first electrical contact covering the substrate, in order to reveal the first and second electrical contacts. The second electrical contact can then be treated and comprise additional layers in comparison to the first electrical contact.

According to one embodiment, the absorber may cover side faces and an upper face of the first electrical contact.

An absorber encapsulating the exposed portions of the first electrical contact helps to prevent any leakage current between the first and second electrical contacts via the electrically conductive transparent layer. Indeed, when the absorber thus encapsulates the first electrical contact, the only viable path for a current traveling through the first electrical contact towards the second electrical contact passes through the absorber.

Advantageously, the second electrical contact may further comprise a material selected among: 316L stainless steel, an alloy of Fe—Cr—Ni—Mo, Ni—Mo—P, MoO₂, ZnO, SnO₂, aluminum-doped ZnO, fluorine-doped tin oxide FTO, steels containing carbon and manganese, compounds based on cobalt and phosphorus.

Such materials, deposited on the second electrical contact, can form a layer protecting the second electrical contact. This layer can protect the second electrical contact from corrosion in an electrolytic bath during deposition of the absorber, or from the high temperatures occurring during an annealing step under a selenium or sulfur atmosphere that can occur during fabrication of the absorber. “High temperature” is understood to mean temperatures typically comprised between 400° C. and 650° C., and more generally the temperatures occurring in annealing during the fabrication of thin-film solar cells. In addition, the layer protects the second electrical contact from selenium vapor, which can be harmful to the metals of the second electrical contact.

According to one embodiment, the photovoltaic device may be a light-concentrating device.

In a light-concentrating photovoltaic device, the arrangement of the two electrical contacts of the invention is suitable for effective transmission of the high current densities occurring in the absorber while limiting the resistive losses from the absorber to the electrical contacts.

According to one embodiment, the photovoltaic device may be in the form of a semi-transparent photovoltaic panel.

The invention, due to the advantageous arrangement of the two electrical contacts on the substrate, allows reducing the surface area of the second electrical contact. Thus, in particular when the photovoltaic device is a panel of light-concentrating solar cells, most of the substrate surface is not covered by either the first electrical contact or the second electrical contact. In the case of a transparent substrate, this feature makes it possible to consider using the photovoltaic device of the invention in window glass integrating a light-concentrating photovoltaic panel.

The invention also relates to a method for fabricating a thin-film photovoltaic device, comprising:
forming at least a first electrically conductive thin layer forming a first electrical contact of the photovoltaic device on a substrate,
forming at least a second electrically conductive thin layer forming a second electrical contact of the photovoltaic device on a substrate,
depositing an absorber on the first electrical contact,
depositing a transparent conductive layer on the absorber,
   the second electrical contact being spaced apart from the first electrical contact, and the transparent conductive layer being in contact with the absorber and the second electrical contact. This method of fabrication offers the advantage of being simple, as it involves the deposition of two electrical contacts directly on the substrate. In addition, this method can be implemented using thin-film solar cell fabrication techniques, without requiring complex alignment machines for positioning the electrical contacts, as they are directly formed on the substrate on the same side of the substrate as the absorber.

According to one embodiment, the method may further comprise:
forming the second electrically conductive thin layer by etching the first electrical contact.

Creating the first and second electrical contacts by etching offers precise control over the space between the two electrical contacts, which can be chosen so that the second electrical contact is as close as possible to the first electrical contact.

Etching further allows controlling the shape of the first and second electrical contacts, so that the second electrical contact is arranged on a more or less large portion of the periphery of the first electrical contact.

Etching also allows obtaining electrical contacts having equivalent electrical properties, the second electrical contact possessing the same layers and substantially the same thickness as the first electrical contact.

According to one embodiment, the method may further comprise:
forming the first and second electrical contacts such that the second electrical contact and the first electrical contact are structured in an interleaved manner.

According to one embodiment, the method may further comprise:
forming the first and second electrical contacts such that the second electrical contact is spaced apart from the first electrical contact by a distance substantially equal to or greater than a thickness of the absorber.

When the second electrical contact is spaced apart from the first electrical contact by a distance substantially equal to or greater than the thickness of the absorber, the absorber can cover the first electrical contact so as to encapsulate it. This encapsulation reduces leakage currents from the first electrical contact to the second electrical contact.

According to one embodiment, depositing the absorber on the first electrical contact may further comprise:

depositing a precursor material of the absorber on the first electrical contact by a technique selected among: electrodeposition, evaporation, ink printing,
incorporating a material selected among selenium and sulfur into the precursor material.

Formation of the absorber by an electrodeposition technique, ink printing, or certain evaporation techniques has the advantage of being carried out in a localized manner, on the first electrical contact only. In this respect, electrodeposition is a particularly reliable technique for selective deposition since it only deposits the precursor on an electrically active surface, such as the first electrical contact for example.

According to one embodiment, the method may further comprise:
forming a corrosion-resistant, electrically conductive material that is stable in selenization or sulfurization, on the second electrical contact.

Such a material protects the second electrical contact from all corrosion during electrodeposition of a layer of the photovoltaic device, and protects this second electrical contact from an annealing step under a selenium or sulfur atmosphere.

According to one embodiment, the method may further comprise:
forming the corrosion-resistant, electrically conductive material that is stable in selenization or sulfurization, by a technique selected among: electrodeposition, thermal oxidation in an oxidizing atmosphere of a conductive layer of the second electrical contact, electrochemical oxidation of a conductive layer of the second electrical contact.

According to one embodiment, the method may further comprise:
treating the corrosion-resistant, electrically conductive material that is stable in selenization or sulfurization, by adding phosphorus.

The addition of phosphorus allows maintaining an amorphous structure in the metal alloys used to protect the second electrical contact, while increasing the corrosion resistance of the contact.

According to one embodiment, the method may further comprise:
depositing an electrically conductive layer on the second electrical contact, subsequent to an annealing step.

This allows repairing any damage caused by the annealing step to the metals of the second electrical contact.

### DESCRIPTION OF FIGURES

The method of the invention will be better understood from reading the following description of some exemplary embodiments presented for illustrative purposes, which are in no way limiting, and from studying the following drawings in which:

FIG. 1 is a schematic side view of a thin-film photovoltaic device according to one embodiment;

FIG. 2 is a schematic top view of a thin-film photovoltaic device according to one embodiment;

FIG. 3 is a schematic representation of six steps of a method for fabricating a photovoltaic device according to one embodiment.

For clarity, the dimensions of the various elements represented in these figures are not necessarily in proportion to their actual dimensions. In the figures, identical references correspond to identical elements.

### DETAILED DESCRIPTION

The present invention relates to a photovoltaic device having electrical contacts arranged in an optimized manner relative to the absorber. The electrical contacts described below are also easier to construct and can be precisely positioned relative to an absorber.

In particular, the invention relates to thin-film solar cells which can be arranged in a solar panel possibly equipped with a light concentration system.

The invention proposes a unique arrangement for the two electrical contacts located near the absorber, which makes it possible to avoid obscuring the absorber and enables simple fabrication as close as possible to the absorber.

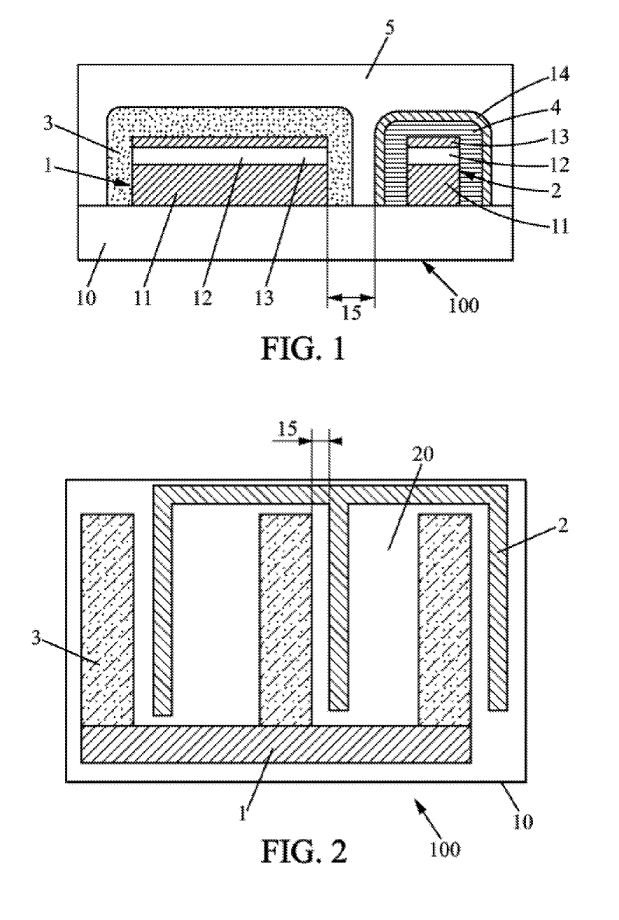

FIG. 1 schematically illustrates a sectional view of a photovoltaic device 100 according to an embodiment of the invention. This photovoltaic device comprises a substrate 10, on which rests a first stack of electrically conductive thin layers forming a first electrical contact 1. A second stack of electrically conductive thin layers forming a second electrical contact 2 rests on the same substrate 10.

Although FIG. 1 illustrates a stack of thin layers, it is possible to use a single layer to form the first and second electrical contacts.

As represented in FIG. 1, the entire lower surface of the two electrical contacts rests on the substrate 10.

In FIG. 1, the first and second electrical contacts are created from the same stack of layers. This stack consists of a conductive layer 11, generally made of metal such as molybdenum having a thickness comprised between 500 nm and 1 μm. Alternatively, this conductive layer 11 may be a transparent conductive oxide such as aluminum-doped ZnO, boron or chlorine, fluorine-doped tin oxide FTO, indium-doped tin oxide ITO, or SnO₂. A barrier layer 12 having a typical thickness of 50 nm of a metal alloy such as MoN or TiN for example serves to protect the conductive layer 11 from a selenization or sulfurization annealing. A metal overlayer 13 arranged on the barrier layer 12 serves to encourage deposition of the absorber on the first electrical contact. This overlayer 13 is usually of molybdenum or copper and has a thickness typically comprised between 50 nm and 300 nm. The Mo overlayer is sacrificial. During annealing, it assists m forming a layer of MoSe₂ which ensures the ohmicity of the electrical contact.

As represented in FIG. 1, the first and second electrical contacts are both arranged on the same face of the substrate 10, on the same side of the substrate 10 as the absorber 3 possessing photovoltaic properties. Given this arrangement, the substrate 10 is electrically insulating according to the representation in FIG. 1, in order to prevent a short circuit between the first and second electrical contacts. However, as an alternative, it is possible to provide an insulating layer on the substrate 10 and below the first and second electrical contacts.

The second electrical contact 2 is separated from the first electrical contact 1 by a space 15. This space 15 makes it possible to electrically separate the second electrical contact 2 from the first electrical contact 1. During fabrication of the first and second electrical contacts, the width of this space 15 can be adjusted, as can the shape of the first and second electrical contacts.

The first electrical contact 1 comprises an absorber 3, on at least its upper surface. The absorber 3, as shown in FIG. 1, also covers the side faces of the first electrical contact 1. Such encapsulation of the first electrical contact 1 by the absorber 3 reduces leakage currents from the first electrical contact 1 towards the second electrical contact 2. However, it is possible that the absorber 3 only partially covers the side surfaces or does not cover them at all. Leakage currents can then be reduced for example by a deposition of an insulating layer in the space 15 between the first electrical contact 1 and the second electrical contact 2.

The second electrical contact 2 may comprise, on at least a portion of its surface, a corrosion-resistant, electrically conductive material 4 that is stable in selenization or sulfurization. This material protects the second electrical contact 2 from the corrosion caused by a possible subsequent step of electrodeposition, as well as from an annealing that could be damaging to metal layers. Annealing in a selenium or sulfur atmosphere typically takes place during fabrication of the absorber 3, subsequent to the deposition of the second electrical contact 2. Preferably, the corrosion-resistant, electrically conductive material 4 that is stable in selenization or sulfurization also has the property of being easy to deposit on a layer of molybdenum or copper, and of having good resistance to ammonia, as ammonia may be involved during the deposition of buffer layers covering the absorber 3.

However, it should noted that the presence of material 4 in the second electrical contact is not necessary. For example when layer 13 is of MoN or TiN, the second electrical contact can withstand annealing without suffering substantial damage.

As a non-limiting example, the corrosion-resistant, electrically conductive material 4 that is stable in selenization or sulfurization can be selected among: 316L stainless steel, an alloy of Fe—Cr—Ni—Mo, Ni—Mo—P, MoO₂, ZnO. SnO₂, aluminum-doped ZnO, fluorine-doped tin oxide FTO, steels containing carbon and manganese, compounds based on cobalt and phosphorus 316L stainless steel is a particularly suitable material for protecting the second electrical contact 2, 316L stainless steel typically consists of 0.02% carbon C, 16% to 18% chromium Cr, 10.5% to 13% nickel Ni, 2% to 2.5% molybdenum Mo, and 2% manganese Mn. The presence of nickel and chromium typically contributes to corrosion resistance in an electrodeposition bath. Chromium reacts with oxygen in the air and forms a chromium oxide layer. Nickel integrates into the oxide layer and improves the properties of the passive layer. The presence of metals such as molybdenum, titanium, or copper can further improve the chemical resistance of the second electrical contact 2, particularly in non-oxidizing environments.

In addition, it is possible to further improve the corrosion resistance of the corrosion-resistant, electrically conductive material 4 that is stable in selenization or sulfurization, by the addition of phosphorus P. Phosphorus promotes the formation of an amorphous structure in an alloy such as 316L stainless steel.

FTO has the characteristic of resistance to selenization or sulfurization for about an hour at temperatures of 600° C. and may also be suitable as material 4. Similarly, aluminum-doped ZnO only partially reacts with seleniun and sulfur at a temperature of 600° C. and may also be suitable as material 4.

As represented in FIG. 1, the second electrical contact 2 may comprise more layers than the first electrical contact 1. In addition to the possible presence of a corrosion-resistant electrically conductive material that is stable in selenization or sulfurization, the second electrical contact may comprise, on its upper surface, a conductive overlayer of an electrically conductive material 14, typically zinc. Metals other than zinc may also be considered. This conductive overlayer allows adjusting the electrical conduction properties of the second electrical contact 2.

Electrical contact between the absorber 3 and the second electrical contact 2 is provided by the transparent electrically conductive layer 5 arranged on the absorber, in contact with the absorber and the second electrical contact. This transparent layer 5 may typically be the window layer of aluminum-doped zinc oxide of the photovoltaic device 100. Alternatively, the transparent layer 5 may for example be chlorine-doped ZnO, boron-doped, ZnMgO, indium-doped tin oxide ITO, or FTO.

This original arrangement of the first and second electrical contacts in the photovoltaic device 100 enables accurate and maximized closeness between the first and second electrical contacts, in order to carry away the high current densities that typically can occur in a light-concentrating solar cell.

In addition to minimizing the space 15, the efficiency with which the electric current generated in the absorber is collected by the first electrical contact 1 and second electrical contact 2 is dependent on the shape of these electrical contacts.

FIG. 2 schematically represents a top view of an exemplary arrangement between the first electrical contact 1 and the second electrical contact 2. The device shown consists of substantially rectangular electrical contacts, arranged so as to form interleaved combs. The structure shown in FIG. 2 is particularly suitable for discharging high current densities in a light-concentrating photovoltaic device 100. The system for focusing the light on the absorber 3 is not shown in FIG. 2.

Given the fact that the first electrical contact 1 is interleaved with the second electrical contact 2, the portion of the second electrical contact 2 facing the first electrical contact is large, while maintaining a small space 15. This allows effectively discharging high current densities while allowing the use of a second electrical contact of reduced dimensions. Thus, as illustrated in FIG. 2, most of the upper surface of the substrate 10 is not covered either by the first electrical contact 1 or the second electrical contact 2. Free space 20 allows incident light to reach the substrate directly and possibly to pass through it. Thus, it is possible to conceive of using the photovoltaic device of the invention in window glass, particularly when the substrate 10 is translucent or transparent.

The interleaved structure shown in FIG. 2 can have many variations. The shapes of the first and second electrical contacts can vary, as can the space 15 between these contacts. One should, however, prefer structures in which the first contact comprises protrusions arranged facing portions of complementary shape created in the second contact, maintaining a substantially constant gap between the first and second contacts along their mutually facing portions. According to an advantageous variant, the ends of the interleaved structure of the first and second electrical contacts may be of trapezoidal shape. The base of the trapezoids of the contacts, near the terminals of the cell, serves to carry away larger amounts of current.

In addition, the shape of the electrical contacts may be chosen so as to give a solar panel a more aesthetic form, particularly when the substrate is transparent and comprises a light concentration system.

The photovoltaic device 100 according to the invention also has the advantage of benefiting from a fabrication method that is particularly simple and inexpensive to implement.

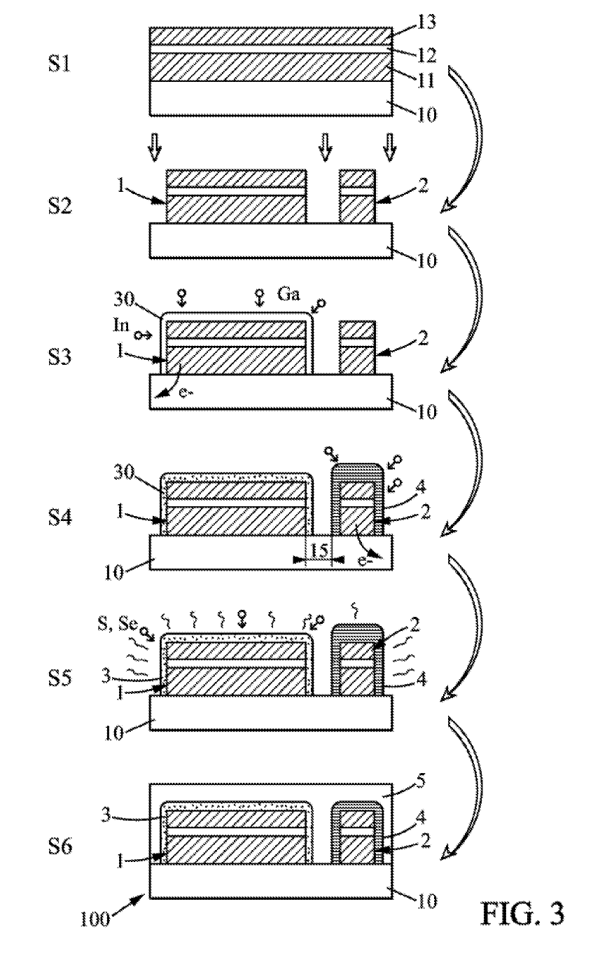

For example, FIG. 3 shows six steps of fabricating a photovoltaic device 100 according to the invention.

A first step S1 may comprise the deposition of at least one metal layer on a substrate 10. In the example of FIG. 3, the substrate is electrically insulating, and a stack of three layers as described above is deposited on its upper surface.

In a second step S2, the stack created in step S1 is etched so that two separate networks forming the first electrical contact 1 and the second electrical contact 2 are exposed in the stack, before the addition of supplemental layers. This etching may be accomplished by laser ablation, electrical discharge machining, or any other known etching process, to create two networks whose spacing is controlled and selected.

As an alternative to these two steps, it is also possible to consider a direct deposition of two networks of distinct metal layers to form the two electrical contacts on the same substrate 10.

Next, in a step S3, an absorber precursor 30 is deposited on the first electrical contact 1. This deposition may be carried out by electrodeposition, a particularly advantageous selective process which uses a current applied to the first electrical contact in order to selectively deposit indium and gallium only on this electrical contact. Other selective processes can be considered, such as ink printing. A selective evaporation process may also be considered. Alternatively, non-selective processes such as sputtering or co-evaporation may be implemented, with the use of a mask.

In addition, an electrically conductive material 14 may be deposited on the upper surface of the second electrical contact 2, preferably after a selenization or sulfurization annealing step. This electrically conductive material 14 may for example be zinc. It may be deposited on at least a portion of the upper surface of the second electrical contact 2, or may cover the upper surface of the second electrical contact 2 and side faces of the second electrical contact.

In a step S4, the corrosion-resistant electrically conductive material 4 that is stable in selenization or sulfurization is formed on the second electrical contact 2. This deposition may occur in different ways. Preferably, it is carried out by selective electrodeposition. This step S4 of formation of material 4 is optional.

Alternatively, it may also be carried out by thermal oxidation in an oxidizing atmosphere, such as air or oxygen, by causing current to flow in the second electrical contact 2 which heats said contact. Thermal oxidation allows oxidizing the molybdenum of the second electrical contact so as to create MoO₂, while controlling various parameters of the oxidation such as the current applied to the second electrical contact 2, the duration of the oxidation, and the concentration of oxidizing agents.

Another variant consists of carrying out an electrochemical oxidation of the molybdenum of the second electrical contact 2, by controlling the electric potential applied to the second electrical contact and the pH of an electrolytic solution into which the sample being fabricated is immersed.

It should be noted that steps S3 and S4 described above can be swapped.

Next, the precursor 30 is thermally annealed under a selenium or sulfur atmosphere in a step S5. The second electrical contact 2 is then protected by the material 4 forming a protective layer around metals otherwise susceptible to damage during this annealing step.

Finally, the fabrication of the photovoltaic device 100) is completed by the possible deposition of a buffer layer and a window layer. The electrically conductive transparent layer 5 ensuring an electrical contact between the absorber 3 and the second electrical contact 2 may be the window layer of the photovoltaic device or another layer. Step S6 schematically represents the photovoltaic device 100 so obtained.

The thin-film photovoltaic device described above and its method of fabrication offer electrical contacts that are accurately positioned as close as possible to an absorber without obscuring the absorber. In addition, the fabrication of this device is facilitated and is less expensive in comparison to the fabrication of devices of the prior art. The photovoltaic device described above is particularly suitable for applications concerning a light-concentrating photovoltaic device.

1: A thin-film photovoltaic device in the form of a semi-transparent photovoltaic panel, comprising:
a substrate,
at least a first electrically conductive thin layer forming a first electrical contact of the photovoltaic device on the substrate,
an absorber arranged on the first electrical contact,
at least a second electrically conductive thin layer forming a second electrical contact of the photovoltaic device on the substrate,
a transparent conductive layer arranged on the absorber,
the second electrical contact being spaced apart from the first electrical contact, and the transparent conductive layer being in contact with the absorber and the second electrical contact.

2: The device according to claim 1, wherein the second electrical contact and the first electrical contact are structured in an interleaved manner.

3: The device according to claim 1, wherein the second electrical contact comprises each of the layers of the first electrical contact.

4: The device according to claim 1, wherein the absorber covers side faces and an upper face of the first electrical contact.

5: The device according to claim 1, wherein the second electrical contact further comprises a material selected among: 316L stainless steel, an alloy of Fe—Cr—Ni—Mo, Ni—Mo—P, MoO₂, ZnO, SnO₂, aluminum-doped ZnO, fluorine-doped tin oxide FTO, steels containing carbon and manganese, compounds based on cobalt and phosphorus.

6: The device according to claim 1, wherein the photovoltaic device is a light-concentrating device.

7: A method for fabricating a thin film photovoltaic device in the form of a semi-transparent photovoltaic panel, comprising:
forming at least a first electrically conductive thin layer forming a first electrical contact of the photovoltaic device on a substrate,
forming at least a second electrically conductive thin layer forming a second electrical contact of the photovoltaic device on the substrate,
depositing an absorber on the first electrical contact,
depositing a transparent conductive layer on the absorber,
the second electrical contact being spaced apart from the first electrical contact, and the transparent conductive layer being in contact with the absorber and the second electrical contact.

8: The method according to claim 7, further comprising:
forming the second electrically conductive thin layer by etching the first electrical contact.

9: The method according to claim 7, further comprising:
forming the first and second electrical contacts such that the second electrical contact and the first electrical contact are structured in an interleaved manner.

10: The method according to claim 7, further comprising:
forming the first and second electrical contacts such that the second electrical contact is spaced apart from the first electrical contact by a distance substantially equal to or greater than a thickness of the absorber.

11: The method according to claim 7, wherein:
depositing the absorber on the first electrical contact further comprises:
depositing a precursor material of the absorber on the first electrical contact by a technique selected among: electrodeposition, evaporation, ink printing,
incorporating a material selected among selenium and sulfur into the precursor material.

12: The method according to claim 7, further comprising:
forming a corrosion-resistant, electrically conductive material that is stable in selenization or sulfurization, on the second electrical contact.

13: The method according to claim 12, further comprising:
forming the corrosion-resistant, electrically conductive material that is stable in selenization or sulfurization, by a technique selected among: electrodeposition, thermal oxidation in an oxidizing atmosphere of a conductive layer of the second electrical contact, electrochemical oxidation of a conductive layer of the second electrical contact.

14: The method according to claim 12, further comprising:
treating the corrosion-resistant, electrically conductive material that is stable in selenization or sulfurization, by adding phosphorus.

15: The method according to claim 7, further comprising:
depositing an electrically conductive layer on the second electrical contact, subsequent to an annealing step.
